(19) United States
(12) Patent Application Publication
(10) Pub. No.: US 2013/0191058 A1
(43) Pub. Date: Jul. 25, 2013

(54) INTELLIGENT ANALYSIS METHOD OF LEAKAGE CURRENT DATA FOR CHIP CLASSIFICATION

(71) Applicant: National Chiao Tung University, Hsinchu City (TW)

(72) Inventors: Charles Hung-Pin WEN, Zhudong Township (TW); Chia-Ling CHANG, Hsinchu City (TW)

(73) Assignee: NATIONAL CHIAO TUNG UNIVERSITY, Hsinchu City (TW)

(21) Appl. No.: 13/633,775

(22) Filed: Oct. 2, 2012

(30) Foreign Application Priority Data
Jan. 19, 2012 (TW) 101102069

(51) Int. Cl. G01R 31/02; G06F 19/00

(52) U.S. Cl. 702/64

(57) ABSTRACT

An intelligent analysis method of leakage current data for chip classification is provided. The analysis method includes steps of: providing a plurality of given patterns to a chip and measuring a plurality of leakage currents of the chip corresponding to the given patterns; finding a minimum value of the leakage currents and deriving an uninfected process parameter according to the minimum value; calculating a plurality of σ-Iddq values based on the uninfected process parameter and the given patterns; and applying a clustering algorithm to the σ-Iddq values to classify whether the chip is a defect-free one. By employing the novel method, it is advantageous of high efficiency and precision without involving any threshold-value determination, visual inspection and/or pattern modification.

### BACKGROUND OF THE INVENTION

1. Field of the Invention

The present invention relates to an analysis method for a semiconductor chip. More specifically, the present invention discloses an analysis method of Iddq data to classify a chip made by CMOS technology and determine if the chip is defect-free.

2. Description of the Prior Art

Iddq testing, also known as leakage current testing, has been a critical integral component in test suites for screening unreliable devices in a CMOS technology. It is a simple and cost-effective testing method which screens defective devices originated from imperfect manufacturing process.

Traditional Iddq testing methods use a single threshold value for classifying chips. Many advanced variants, such as “A. Gattiker and W. Maly, Current signatures [vlsi circuit testing], in Proc. VTS, pp. 112, 1996”, “A. Miller, Iddq testing in deep submicron integrated circuits, in Proc. ITC, 1999.”, “T. J. Powell, J. Pair, M. St. John, and D. Counce, Delta iddq for testing reliability, in Proc. VTS, pp. 439-443, 2000”, and “P. Maxwell, P. O'Neill, R. Aitken, R. Dudley, N. Jaarsma, M. Quach, and D. Wiseman, Current ratios: a self-scaling technique for production iddq testing, in Proc. ITC, pp. 738-746, 1999” are proposed also to reduce variance in fault-free Iddq, involving in current signature, Δ-Iddq, current ratio and so on. Although these prior methods are quite simple and easy to implement, the screening resolutions of these methods have to depend on the quality of Iddq measurement and requires a threshold value to classify whether chips are defect-free or not. Besides, the threshold value is not trivial to determine, whereby increasing complexity of these testing methods.

Wafer-level spatial correlation methods, including “S. Sabade and D. Walker, Improved wafer-level spatial analysis for iddq limit setting, in Proc. ITC, 2001”, “P. Nigh and A. Gattiker, Random and systematic defect analysis using iddq signature analysis for understanding fails and guiding test decisions, in Proc. ITC, pp. 309-318, 2004”, “Sagar S. Sabade, D. M. H. Walker, Neighbor Current Ratio (NCR): a new metric for IDDQ data analysis, in Proc. DFT, 2002”, graphical Iddq “L. Rao, M. L. Bushnell, and V. D. Agrawal, New graphical iddq signatures reduce defect level and yield loss, in Proc. VLSI Design, pp. 353-360, 2003.”, and CΔIddq “C. Thibeault and Y. Hariri, CΔIddq: Improving current-based testing and diagnosis through modified test pattern generation, TVLSI, vol. 19, no. 1, pp. 130-141, 2011”, are also proposed later to combat the decreasing effectiveness of Iddq testing. These spatial-based methods (disclosed in “S. Sabade and D. Walker, Improved wafer-level spatial analysis for iddq limit setting, in Proc. ITC, 2001”, and “P. Nigh and A. Gattiker, Random and systematic defect analysis using iddq signature analysis for understanding fails and guiding test decisions, in Proc. ITC, pp. 309-318, 2004.”) requires a predetermined threshold value to classify chips according to the location of each chip on the wafer. Nearest neighbors are used as references to provide a basis during Iddq comparison.

However, the threshold value is wafer-dependent and hard to be extended to other wafers. In other words, every different wafer has its own distinct threshold value. To decide these threshold values, graphical Iddq method of prior art has to remove outliers on current signatures to improve classification results. Nevertheless, it requires visual identification by engineers, and therefore consumes much more human sources.

Furthermore, CΔIddq of the abovementioned prior-art uses variance reduction against the process-variation effect. However, test modification for Iddq patterns is particularly required in CΔIddq technology. Moreover, along with process variation, the ever increasing design complexity makes Iddq testing more challenging from two aspects: (1) the leakage current due to a defect becomes relatively small in a scaled design; and (2) the leakage currents of normal cells grow remarkably with the increasing process variation. As a result, Iddq distributions of good (defect-free) chips and bad (defective) chips become more indistinguishable and thus unavoidably result in more test escapes and yield loss.

FIG. 1A and FIG. 1B illustrate this situation under two different technologies, 90 nm and 45 nm relatively. The distributions in FIG. 1A and FIG. 1B represent Iddq simulation on one ISCAS'85 benchmark circuit, wherein each bad chip is produced by injecting one random defect. As shown in FIG. 1A, it can be seen that it is impossible to prevent test escapes and/or yield loss once a threshold is decided. Moreover, all defective (bad) chips in a 45 nm technology all become test escapes as in FIG. 1B and therefore cannot be separated because the Iddq distribution of the bad chips is entirely encompassed in the Iddq distribution of the good chips. As a result, the increasing test-escape chips may lead to an extra cost for circuit designs. To prevent this problem from occurring, a novel analysis method for Iddq data is highly required to pinpoint the root cause.

FIG. 2A and FIG. 2B further show Iddq currents in a 45 nm technology of a defect-free chip and a defective chip, relatively. As shown in FIG. 2A and FIG. 2B, it is difficult to differentiate these two figures according to their Iddq distributions. For example, FIG. 2A and FIG. 2B seem no different if every circle denoting one Iddq including the defect-induced faulty leakage is not marked as grey in FIG. 2B. Thus, a misclassification may lead to either a test escape or yield loss.

Δ-Iddq and current ratio may also be applied to handle the inscrutable Iddq currents in FIG. 2A. Δ-Iddq attempts to remove the pattern-dependent effect by computing differences between Iddq values of successive patterns for making decisions. Current ratio, the ratio of maximum Iddq to minimum Iddq on each chip, finds a regression function so that the defective chips can be identified as outliers. In FIG. 3A, Δ-Iddq has the same difficulty in deciding a precise threshold value whereas in FIG. 3B, current ratio of defect-free-chips and defective-chips are lined up similarly and unable to be separated from each other. Therefore, the persons skilled in the art are eager to develop a novel analysis method for distinguishing if a chip is defective and being able to effectively overcome the abovementioned problems.

### SUMMARY OF THE INVENTION

To achieve these and other advantages and in order to overcome the disadvantages of the conventional method in accordance with the purpose of the invention as embodied and broadly described herein, the present invention provides an intelligent analysis method for leakage current (Iddq) test data to successfully screen out defective chips.

In one aspect, the intelligent analysis method of leakage current data for chip classification of the present invention comprises steps of providing a plurality of given patterns to a chip and measuring a plurality of leakage currents (Iddq) of the chip corresponding to the given patterns; finding a minimum value of the leakage currents and deriving an uninfected process parameter according to the minimum value; calculating a plurality of σ-Iddq values based on the uninfected process parameter and the given patterns; and applying a clustering algorithm to the σ-Iddq values to classify whether the chip is defect-free.

According to one embodiment of the present invention, wherein

σ-Iddq=Iddq−̂Iddq(x;y;P)

Iddq represents the leakage currents, ̂Iddq represents estimated leakage currents, x and y represent axis coordinates located on the chip, and P is consisting of the uninfected process parameter and/or the given patterns.

According to one embodiment of the present invention, wherein the step of deriving the uninfected process parameter according to the minimum value of the leakage currents further comprises using an equation of

$$arg {min}_{δ {L}_{eff} , δ {T}_{ox}} ⌊ Iddq - \hat{} Iddq ( δ {L}_{eff} , δ {T}_{ox} ) ⌋$$

wherein δL_{eff} and δTₒₓ represent the process variation of an effective channel length and an oxide thickness of the chip, relatively, and the uninfected process parameter is consisting of δL_{eff} and δTₒₓ.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1A and FIG. 1B illustrate conventional Iddq currents under two different technologies, 90 nm and 45 nm relatively.

FIG. 2A and FIG. 2B illustrate conventional Iddq currents in a 45 nm technology of a defect-free chip and a defective chip, relatively.

FIG. 3A illustrates a result of indistinguishable defect-free and defective chips using conventional Δ-Iddq technology.

FIG. 3B illustrates a result of indistinguishable defect-free and defective chips using conventional current-ratio technology.

FIG. 4 is a flow chart illustrating steps of an intelligent analysis method of Iddq data for chip classification in accordance with one embodiment of the present invention.

FIG. 5A is a schematic view showing normalized σ-Iddq values of a defect-free chip in accordance with one embodiment of the present invention.

FIG. 5B is a flow chart illustrating steps of applying the clustering algorithm to σ-Iddq values for classifying a defect-free chip in accordance with one embodiment of the present invention.

FIG. 6A is a schematic view showing normalized σ-Iddq values of a defective chip in accordance with one embodiment of the present invention.

FIG. 6B is a flow chart illustrating steps of applying the clustering algorithm to σ-Iddq values for classifying a defective chip in accordance with one embodiment of the present invention.

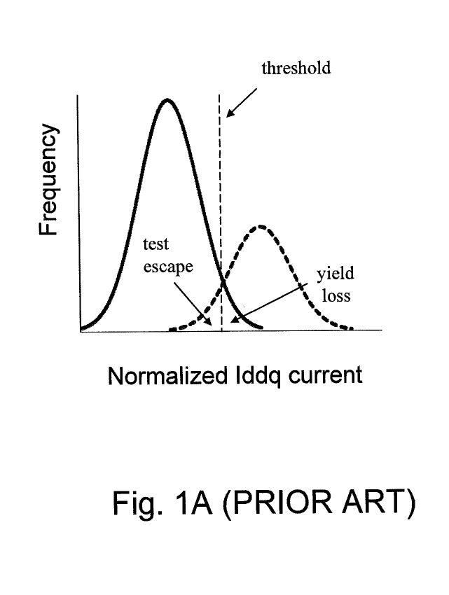

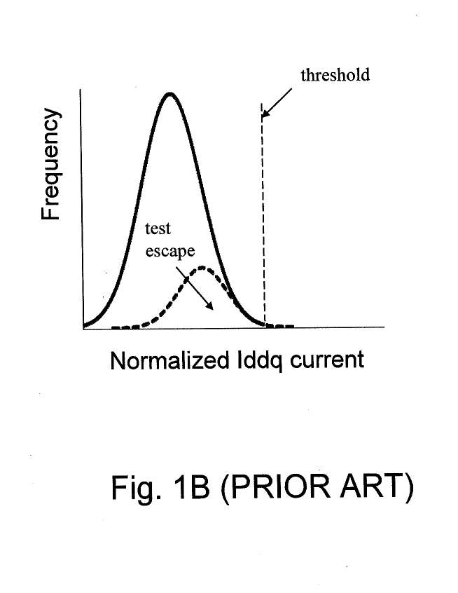

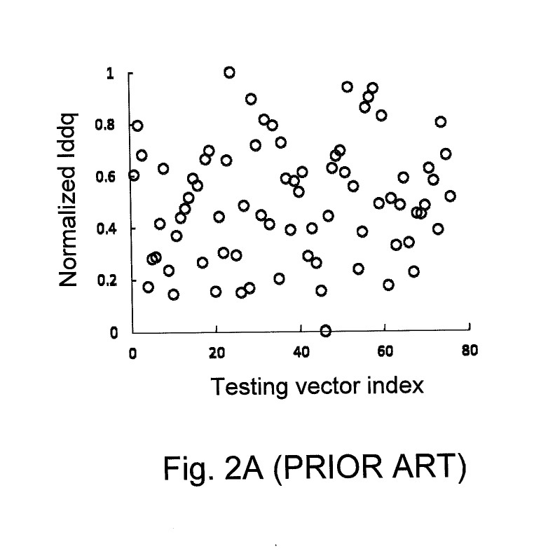

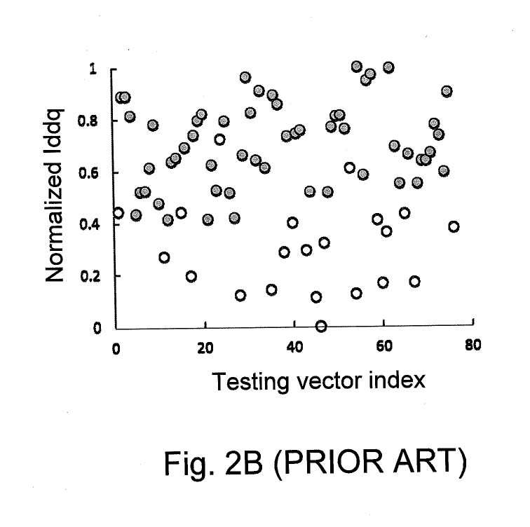

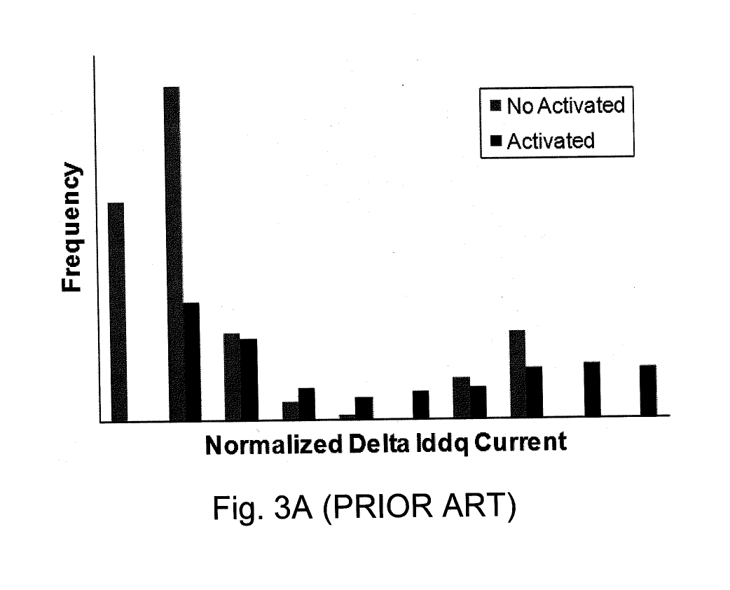

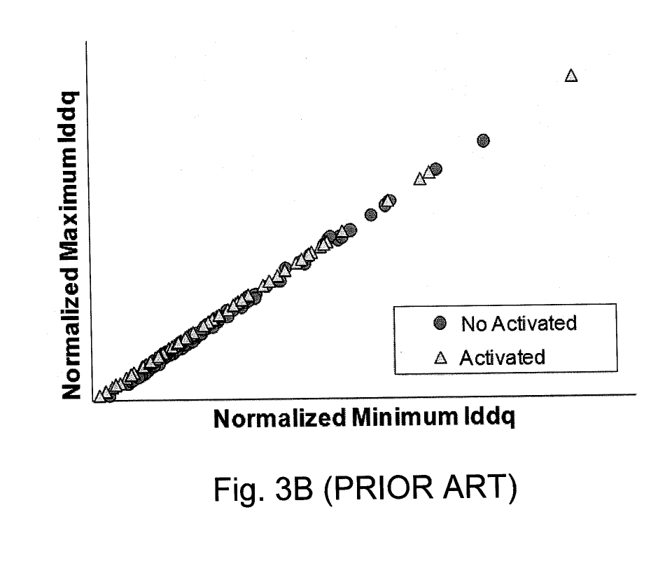

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

Since it is difficult to conclude that the large Iddq value (leakage current) is contributed from process variation or induced by defects, many prior arts have similar difficulties deciding good or bad chips from direct Iddq testing data. Moreover, the number of test-escape chips becomes larger, which may lead to an incredible cost in circuit design. To prevent above problems, the present invention provides an intelligent analysis method for leakage current (Iddq) testing data to successfully classify whether a chip is defect-free or defective.

The proposed invention lends itself well to integrate a variation-aware full-chip leakage estimator and a clustering algorithm to classify chips without using threshold values to resolve the Iddq testing issue. Note that most researches on Iddq testing focus on data analysis, and only “C. Thibeault and Y. Hariri, CΔIddq: Improving current-based testing and diagnosis through modified test pattern generation, TVLSI, vol. 19, no. 1, pp. 130-141, 2011” uses domain knowledge (netlist) to incorporate data analysis to enhance the classification rate. However, the proposed invention does not involve any threshold-value determination, visual inspection and/or pattern modification. Therefore, it is much more efficient and costless.

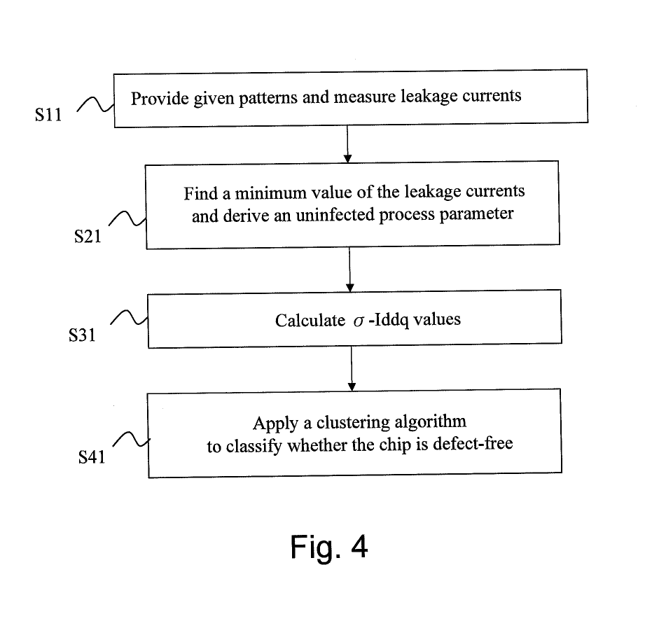

First of all, please refer to FIG. 4, which is a flow chart illustrating steps of an intelligent analysis method of Iddq data for chip classification in accordance with one embodiment of the present invention.

As shown in FIG. 4, the analysis method of the present invention comprises steps S11˜S41. First, in step S11, a plurality of given patterns are provided to a chip and a plurality of leakage currents of the chip corresponding to these given patterns are measured as Iddq values. According to one embodiment of the present invention, these given patterns are different testing vectors provided to the chip and after the chip is provided with a certain testing vector, its leakage current under the testing vector is measured and recorded for further analysis.

In step S21, a minimum value of the Iddq values will be found such that an uninfected process parameter will be derived accordingly. According to one embodiment of the present invention, the uninfected process parameter is derived based on the Equation below:

$$arg {min}_{δ {L}_{eff} , δ {T}_{ox}} ⌊ Iddq - \hat{} Iddq ( δ {L}_{eff} , δ {T}_{ox} ) ⌋ \qquad ( 1 )$$

wherein Iddq represents the minimum value of the leakage currents measured in step S11, ̂Iddq represents estimated leakage currents, δL_{eff} represents the variation of an effective channel length of the chip, δTₒₓ represents the variation of an oxide thickness of the chip, and the uninfected process parameter is consisting of δL_{eff} and δTₒₓ.

The objective of this step is to deduce the average-case process parameters and use the derived uninfected process parameter as the average-case one.

Later, in step S31, based on the uninfected process parameter derived in step S21 and the given patterns provided in S11, a plurality of σ-Iddq values can be calculated, wherein

σ-Iddq=Iddq−̂Iddq(x;y;P) (2)

Iddq represents the leakage currents measured in step S11, ̂Iddq represents estimated leakage currents, x and y represent axis coordinates located on the chip, and P is consisting of the uninfected process parameter and/or the given patterns.

According to one embodiment of the present invention, the method redefines the estimated Iddq in Equation (2) by predicting average-case process variation to support a modified high-quality full-chip leakage estimator and transform the originally-measured Iddq values into σ-Iddq. In other words, σ-Iddq is calculated and defined as the difference between the measured Iddq and the estimated Iddq (̂Iddq) computed from a good die.

In one embodiment, the estimated leakage currents (̂Iddq) can be derived by a full-chip leakage estimator. In other embodiments, the estimated leakage currents (̂Iddq) can also be derived by other leakage estimator. The present invention is not limited thereto.

Finally, in step S41, a clustering algorithm compares the measured Iddq with the average-case Iddq, which is computed by the process parameters found in previous steps, and then intelligently decides the defect activation to classify chips.

That is to say, a clustering algorithm is used to perform onto the σ-Iddq values derived in step S31 and to classify automatically whether the chip is a defect-free chip or a defective one.

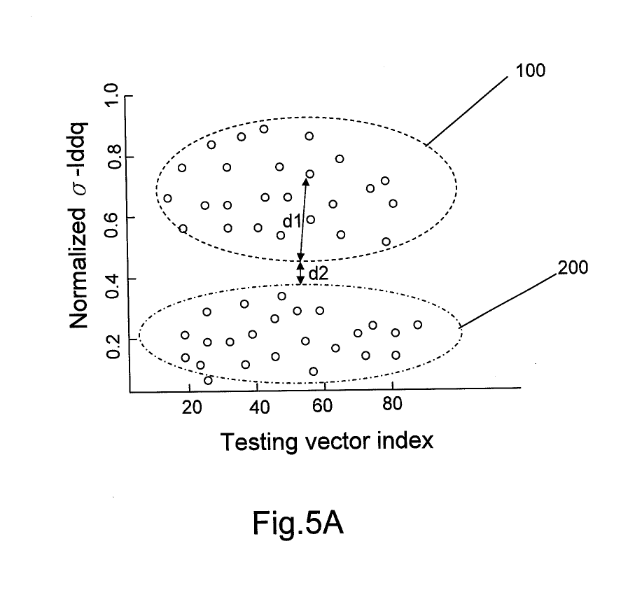

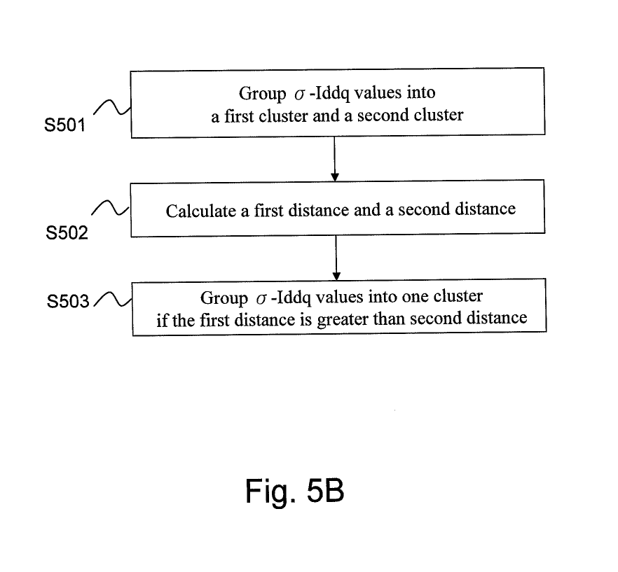

Refer to FIG. 5A, which shows normalized σ-Iddq values of a defect-free chip in accordance with one embodiment of the present invention. FIG. 5B is a flow chart illustrating steps of applying the clustering algorithm to σ-Iddq values for classifying a defect-free chip in accordance with one embodiment of the present invention.

As shown in FIGS. 5A and 5B, in step S501, the σ-Iddq values are initially grouped into two clusters, a first cluster 100 and a second cluster 200. In step S502, a first distance d1 which is from one of the σ-Iddq values to a center of the first cluster 100, and a second distance d2, from the same σ-Iddq value where d1 is calculated to the boundary of the second cluster 200 are calculated, relatively. In step S503, determine if the first distance d1 is less than the second distance d2.

In FIG. 5A, it is obvious that the first distance d1 is greater than the second distance d2. That is to say, the whole σ-Iddq values should be considered to be only one cluster. Thereinafter, in this embodiment of the present invention, when the clustering algorithm groups the σ-Iddq values into only one cluster, then the chip is classified as a defect-free one.

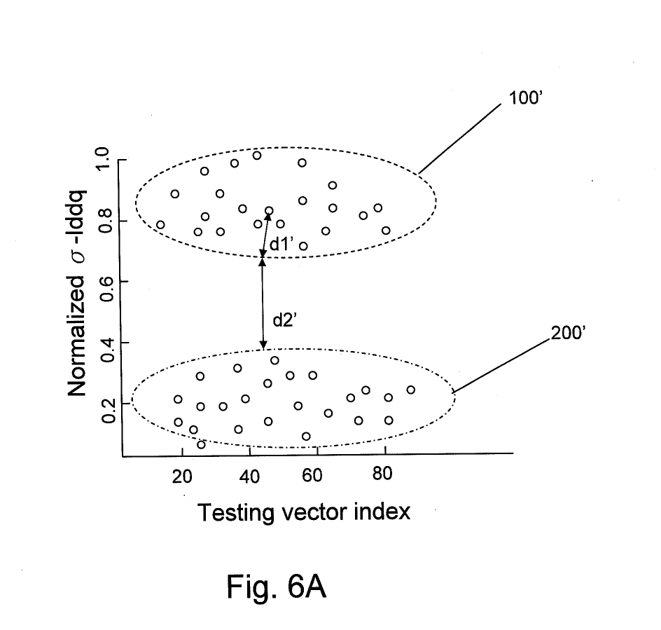

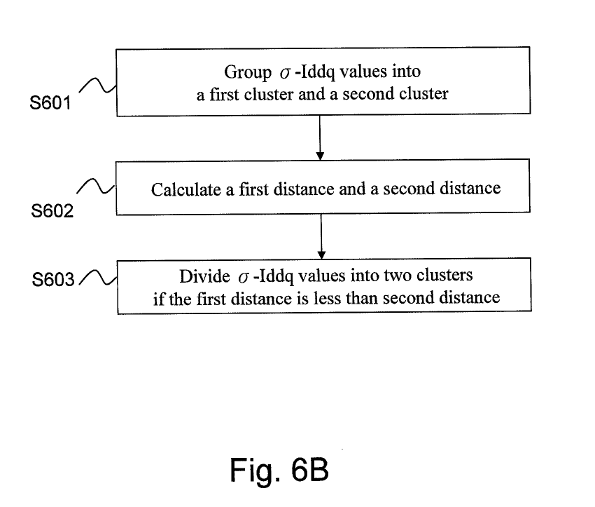

Next, refer to FIG. 6A, which shows normalized σ-Iddq values of a defective chip in accordance with one embodiment of the present invention. FIG. 6B is a flow chart illustrating steps of applying the clustering algorithm to σ-Iddq values for classifying a defective chip in accordance with one embodiment of the present invention.

As shown in FIGS. 6A and 6B, in step S601, the σ-Iddq values are initially grouped into two clusters, a first cluster 100′ and a second cluster 200′. In step S602, a first distance d1′ which is from any of the σ-Iddq values to a center of the first cluster 100′, and a second distance d2′, from the same σ-Iddq value where d1′ is calculated to the boundary of the second cluster 200′ are calculated, relatively. In step S603, determine if the first distance d1′ is less than the second distance d2′.

In FIG. 6A, it can be seen that the first distance d1′ is less than the second distance d2′. That is to say, the whole σ-Iddq values should be divided into two clusters 100′ and 200′. Thereinafter, in the embodiment FIG. 6A shows of the present invention, when the clustering algorithm divides the σ-Iddq values into two clusters, then the chip is classified as a defective one.

According to embodiments of the present invention, the above-mentioned algorithm is a K-means algorithm. However it should be noticed that the proposed invention is fully described abovementioned but not limited thereto. Any persons skilled in the art that have various modifications and variations can be made to the present invention without departing from the scope or spirit of the invention, and nevertheless still fall within the scope of the invention and its equivalent.

As such, the analysis method of the present invention is a pure data-analysis technique and does not require threshold-value determination, additional patterns generation or pattern modification.

Details of the present invention are fully disclosed and described in detail, that the proposed σ-Iddq analysis method includes (1) the transformation from the original Iddq into the σ-Iddq under an assumption of average-case process variation, and (2) a new clustering algorithm to avoid single-threshold determination and thus classify chips automatically. Below shows the experimental settings and experimental results of the present invention demonstrated.

ISCAS'85 and ISCAS'89 are used as benchmark circuits to evaluate the proposed σ-Iddq testing for classifying chips. All circuits are synthesized with Design Complier from Synopsys and run place-and-route with SOC Encounter from Cadence using the Nangate 45 nm Open Cell library.

For simplicity, only primitive cells, e.g. NAND2, NOR2, AND2, OR2, INV and BUF, are used. Nominal values of L_{eff} and Tₒₓ are 50 nm and 1.1 nm, respectively, from the specification of the Nangate library. In this work, the process variation is set to 3σ=20% and includes inter-die and intra-die variations. With a certain setting, inter-die variation contributes 40% of overall process variation while intra-die variation contributes the other 60%.

TABLE 1
Chip-classification results for Iddq under a 5.5 μA defective leakage

| | Single-Threshold Iddq | | | | | Clustering-based Auto-classification | | | | | | | | | |
|---|---|---|---|---|---|---|---|---|---|---|---|---|---|---|---|
| | (w/ golden answers) | | | | | (w/o golden answers) | | | | | | | | | |
| | — | | | | | direct clustering | | | | | σ-Iddq + clustering | | | | |
| Circuit | Positive | | Negative | | | Positive | | Negative | | | Positive | | Negative | | |
| Name | True | False | True | False | Accuracy % | True | False | True | False | Accuracy % | True | False | True | False | Accuracy % |
| c499 | 800 | 200 | 0 | 0 | 80.00 | 800 | 4 | 196 | 0 | 99.60 | 800 | 0 | 200 | 0 | 100 |
| c880 | 800 | 200 | 0 | 0 | 80.00 | 800 | 7 | 193 | 0 | 99.30 | 800 | 0 | 200 | 0 | 100 |
| c1908 | 795 | 199 | 1 | 5 | 79.60 | 800 | 7 | 193 | 0 | 99.30 | 797 | 0 | 200 | 3 | 99.70 |
| c2670 | 799 | 199 | 1 | 1 | 80.00 | 800 | 21 | 179 | 0 | 97.90 | 798 | 0 | 200 | 2 | 99.80 |
| c3540 | 800 | 200 | 0 | 0 | 80.00 | 800 | 61 | 139 | 0 | 93.90 | 797 | 0 | 200 | 3 | 99.70 |
| c6288 | 800 | 200 | 0 | 0 | 80.00 | 800 | 79 | 121 | 0 | 92.10 | 800 | 21 | 179 | 0 | 97.90 |
| c5315 | 800 | 200 | 0 | 0 | 80.00 | 800 | 76 | 124 | 0 | 92.40 | 798 | 1 | 199 | 2 | 99.70 |
| c7552 | 800 | 200 | 0 | 0 | 80.00 | 800 | 97 | 103 | 0 | 90.30 | 798 | 3 | 197 | 2 | 99.50 |
| s5378 | 800 | 200 | 0 | 0 | 80.00 | 800 | 76 | 124 | 0 | 92.40 | 800 | 6 | 194 | 0 | 99.40 |
| s9234 | 800 | 200 | 0 | 0 | 80.00 | 800 | 141 | 59 | 0 | 85.90 | 799 | 7 | 193 | 1 | 99.20 |
| s13207 | 800 | 200 | 0 | 0 | 80.00 | 800 | 183 | 17 | 0 | 81.70 | 800 | 36 | 164 | 0 | 96.40 |
| s15850 | 800 | 200 | 0 | 0 | 80.00 | 800 | 186 | 14 | 0 | 81.40 | 800 | 65 | 135 | 0 | 93.50 |
| Average | | | | | 79.97 | | | | | 92.18 | | | | | 98.73 |

Pseudo stuck-at fault (PSA) model proven to detect all leakage faults is used in this work for experiments. A pseudo stuck-at fault can be represented as a resistor short between supply voltage and output of cell or short connecting from the output of cell and ground. Corresponding to real defective leakage currents in VDSM CMOS designs, big resistors are used in the SPICE simulation to induce small leakage currents. Therefore, two resistance values, 200KΩ and 500KΩ, are used to induce 5.5 μA and 2.2 μA leakage currents as the supply voltage is 1.1V.

1000 samples for each circuit with inter-die and intra-die variations are generated to mimic the real manufacturing process. A pseudo stuck-at fault is randomly injected onto 200 samples and Iddq patterns generated by Synopsys TetraMax are simulated to derive the full-chip leakage. Single-defect assumption is used in the experiments instead of multiple defects since multiple defects induce larger leakage currents than a single defect does. Therefore, the defective chips with multiple defects are easier to be identified.

To demonstrate the power of the σ-Iddq testing, the present invention uses an ideal single threshold method as a baseline approach. Since it is difficult to determine the exact threshold value for single-threshold Iddq, the present invention refers the golden answers to deriving the best performance. That is, the search of best threshold starts from the smallest value to the largest one and terminates when the one with the least number of mis-classifications is found. Therefore, each pattern can derive its own golden threshold value to classify chips. Once a sample is classified as bad chip by one pattern, it is marked as a bad chip afterwards. Similarly, if a sample is claimed as a good chip, it must be good under all patterns. The classification results of such single-threshold Iddq are shown in Table 1. In Table 1, three types of classification results are listed.

True positive (TP) denotes the number of samples that are true fault-free samples and identified as good ones. False positive (FP) denotes the number of fault-free samples claimed as good ones but actually are defective. True negative (TN) denotes the number of true faulty samples and also marked as bad ones. Last, false negative (FN) denotes the number of true fault-free samples mistakenly identifying as bad ones. A good classification method is expected to identify true positive and true negative samples as many as possible. The present invention uses the following equation (3) to define the classification accuracy:

$$Accuracy = \frac{TP + TN}{TP + FP + TN + FN} \qquad ( 3 )$$

where FP together with FN denotes the number of mis-classifications. As a result, single-threshold Iddq can only reach the best accuracy as 79.97% on average for all circuits in Table 1.

Before showing the results of the σ-Iddq testing, the present invention also applies the clustering algorithm directly onto the original Iddq data without referring golden answers (termed direct clustering). Consequently, the algorithm of the present invention can classify the chips effectively and efficiently. As shown in Table 1, the second major column lists the performance of direct clustering and an accuracy of 92.18% on average is reached, higher than single-threshold Iddq by 12%. More specifically, based on original Iddq data, only 922 out of 1000 samples can be successfully identified by the direct clustering. The total execution time including the σ-Iddq and clustering does not exceed 100 seconds for each benchmark.

Last, the σ-Iddq testing (termed σ-Iddq+clustering) achieves the highest accuracy in Table 1. After transforming the original Iddq data into the σ-Iddq, the clustering algorithm can identify bad chips more effectively. As a result, the classification accuracy of σ-Iddq testing shown in Table 1 is on average 98.73%, even higher than direct clustering by 6%. In other words, 60 more chips can be intelligently identified using the σ-Iddq testing of the present invention.

TABLE 2
Chip-classification results for Iddq under a 2.2 μA defective leakage

| | Single-Threshold Iddq | | | | | Clustering-based Auto-classification | | | | | | | | | |
|---|---|---|---|---|---|---|---|---|---|---|---|---|---|---|---|
| | (w/ golden answers) | | | | | (w/o golden answers) | | | | | | | | | |
| | — | | | | | direct clustering | | | | | σ-Iddq + clustering | | | | |
| Circuit | Positive | | Negative | | | Positive | | Negative | | | Positive | | Negative | | |
| Name | True | False | True | False | Accuracy % | True | False | True | False | Accuracy % | True | False | True | False | Accuracy % |
| c499 | 800 | 200 | 0 | 0 | 80.00 | 800 | 44 | 156 | 0 | 95.60 | 800 | 3 | 197 | 0 | 99.70 |
| c880 | 791 | 198 | 2 | 9 | 79.30 | 800 | 116 | 84 | 0 | 88.40 | 800 | 8 | 192 | 0 | 99.20 |
| c1908 | 800 | 200 | 0 | 0 | 80.00 | 800 | 46 | 154 | 0 | 95.40 | 797 | 1 | 199 | 3 | 99.60 |
| c2670 | 799 | 200 | 0 | 1 | 79.90 | 800 | 131 | 69 | 0 | 86.90 | 798 | 2 | 198 | 2 | 99.60 |
| c3540 | 800 | 200 | 0 | 0 | 80.00 | 800 | 185 | 15 | 0 | 81.50 | 797 | 18 | 182 | 3 | 97.90 |
| c6288 | 800 | 200 | 0 | 0 | 80.00 | 800 | 190 | 10 | 0 | 81.00 | 800 | 56 | 144 | 0 | 94.40 |
| c5315 | 800 | 200 | 0 | 0 | 80.00 | 800 | 188 | 12 | 0 | 81.20 | 798 | 26 | 174 | 2 | 97.20 |
| c7552 | 800 | 200 | 0 | 0 | 80.00 | 800 | 198 | 2 | 0 | 80.20 | 798 | 34 | 166 | 2 | 96.40 |
| s5378 | 800 | 200 | 0 | 0 | 80.00 | 800 | 188 | 12 | 0 | 81.20 | 800 | 31 | 169 | 0 | 96.90 |
| s9234 | 800 | 200 | 0 | 0 | 80.00 | 800 | 198 | 2 | 0 | 80.20 | 799 | 36 | 164 | 1 | 96.30 |
| s13207 | 800 | 200 | 0 | 0 | 80.00 | 800 | 199 | 1 | 0 | 80.10 | 800 | 98 | 102 | 0 | 90.20 |
| s15850 | 800 | 200 | 0 | 0 | 80.00 | 800 | 200 | 0 | 0 | 80.00 | 800 | 110 | 90 | 0 | 89.00 |
| Average | | | | | 79.93 | | | | | 84.31 | | | | | 96.37 |

Moreover, as the defective leakage is set smaller (2.2 μA) as used in Table 2, single-threshold Iddq and direct clustering can only result in 79.93% and 84.31% accuracy on average, respectively, due to the process-variation and design scaling impacts. However, the σ-Iddq testing can still achieve 96.37% accuracy. As a result, the σ-Iddq transformation together with the clustering algorithm can successfully screen defective chips for VDSM scaled designs.

To sum up, the present invention provides an intelligent analysis method for Iddq testing data, which integrates (1) a variation-aware full-chip leakage estimator and (2) a clustering algorithm for chip classification. The overall analysis flow originates from finding an uninfected pattern to deduce average-case process variation imposed on every cell. Later, a full-chip leakage estimator is used to find a good set of process parameters and helps to compute the residual current to indicate if a defect is activated on the chip. Last, the clustering algorithm of the present invention automatically classifies chips without requiring a threshold value. Experimental result shows 98.73% (96.37%) accuracy on average for a small defective leakage 5.5 μA (2.2 μA) on benchmark circuits in a 45 nm technology. As a result, it is obvious that the proposed σ-Iddq analysis method effectively removes both the process-variation and design-scaling impacts from original Iddq data and intelligently detects defective chips.

What is claimed is:

1. An intelligent analysis method of leakage current data for chip classification, comprising steps of:
providing a plurality of given patterns to a chip and measuring a plurality of leakage currents (Iddq) of said chip corresponding to said given patterns;
finding a minimum value of said leakage currents and deriving an uninfected process parameter according to said minimum value of said leakage currents;
calculating a plurality of σ-Iddq values based on said uninfected process parameter and said given patterns; and
applying a clustering algorithm to said σ-Iddq values to classify whether said chip is defect-free.

2. The intelligent analysis method of leakage current data of claim 1, wherein
σ-Iddq=Iddq−̂Iddq(x;y;P)
Iddq represents said leakage currents, ̂Iddq represents estimated leakage currents, x and y represent axis coordinates located on said chip, and P is consisting of said uninfected process parameter and/or said given patterns.

3. The intelligent analysis method of leakage current data of claim 2, wherein said deriving said uninfected process parameter according to said minimum value of said leakage currents further comprises using an equation of
$$arg {min}_{δ {L}_{eff} , δ {T}_{ox}} ⌊ Iddq - \hat{} Iddq ( δ {L}_{eff} , δ {T}_{ox} ) ⌋$$
wherein δL_{eff} represents variation of an effective channel length of said chip, δTₒₓ represents variation of an oxide thickness of said chip, and said uninfected process parameter is consisting of δL_{eff} and δTₒₓ.

4. The intelligent analysis method of leakage current data of claim 1, wherein said applying said clustering algorithm to said σ-Iddq values further comprises:
grouping said σ-Iddq values into a first cluster and a second cluster;
calculating a plurality of first distance from said σ-Iddq values to a center of said first cluster and a plurality of second distance from said σ-Iddq values to a boundary of said second cluster; and
dividing said σ-Iddq values into two clusters if said first distance is less than said second distance.

5. The intelligent analysis method of leakage current data of claim 4, further comprising when said clustering algorithm divides said σ-Iddq values into said two clusters, said chip is classified as a defective chip.

6. The intelligent analysis method of leakage current data of claim 1, wherein said applying said clustering algorithm to said σ-Iddq values further comprises:
grouping said σ-Iddq values into a first cluster and a second cluster;
calculating a plurality of first distance from said σ-Iddq values to a center of said first cluster and a plurality of second distance from said σ-Iddq values to a boundary of said second cluster; and
grouping said σ-Iddq values into one cluster if said first distance is more than said second distance.

7. The intelligent analysis method of leakage current data of claim 6, further comprising when said clustering algorithm groups said σ-Iddq values into said one cluster, said chip is classified as a defect-free chip.

8. The intelligent analysis method of leakage current data of claim 1, wherein said given patterns are testing vectors.

9. The intelligent analysis method of leakage current data of claim 1, wherein said estimated leakage currents are derived by a full-chip leakage estimator.

10. The intelligent analysis method of leakage current data of claim 1, wherein said clustering algorithm is a K-means algorithm.
